(19) United States
(12) Patent Application Publication
(10) Pub. No.: US 2010/0209852 A1
(43) Pub. Date: Aug. 19, 2010

(54) TRACK NOZZLE SYSTEM FOR SEMICONDUCTOR FABRICATION

(75) Inventors: Hsiao-Wei Yeh, Jhudong Township (TW); Chi-Kang Chang, Taipei (TW); Jian-Hong Chen, Hsin-Chu (TW); Kuo-Chun Huang, Sinfong Township (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/389,279

(22) Filed: Feb. 19, 2009

(51) Int. Cl. G03F 7/00; B05B 7/00; B05C 11/00; H01L 21/02

(52) U.S. Cl. 430/311; 118/300; 118/666; 438/758; 257/E21.002

(57) ABSTRACT

The present disclosure provides a method for fabricating a semiconductor device using a track pipeline system. The method includes storing a plurality of chemicals in a plurality of storage units of the system, wherein each storage unit is operable to store one of the chemicals, mixing the chemicals into a mixture, and dispensing the mixture onto a wafer using a nozzle of the system.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

To manufacture these scaled-down semiconductor devices, various processes may be employed wherein one or more chemicals may be dispensed onto a wafer. Traditional methods of dispensing the chemicals may be inefficient and ineffective.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart illustrating a method for fabricating a semiconductor device according to various aspects of the present disclosure; and

FIGS. 2-5 are diagrammatic views of a system for fabricating a semiconductor device according to various aspects of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

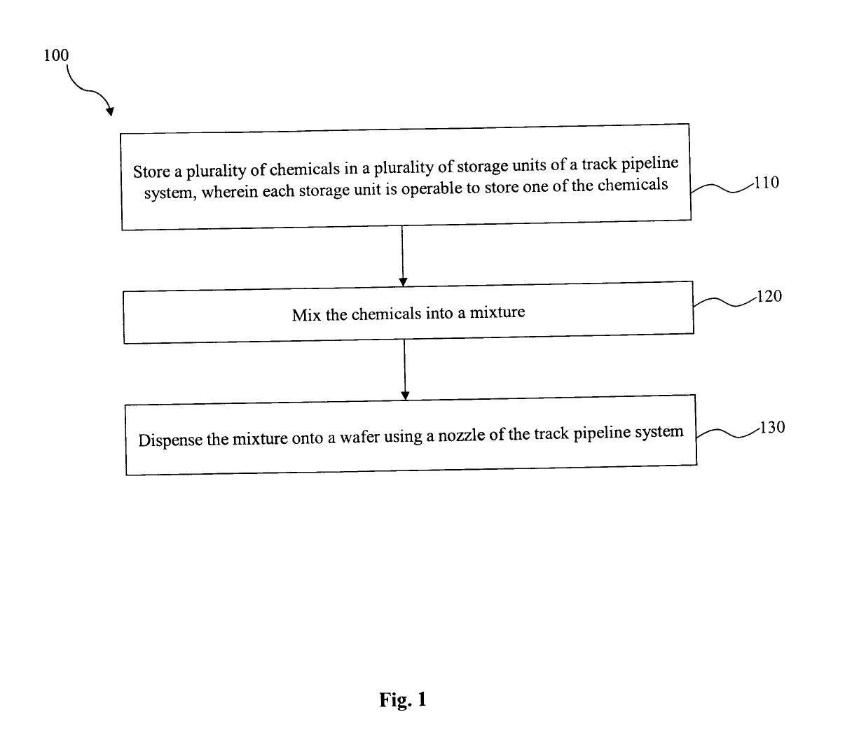

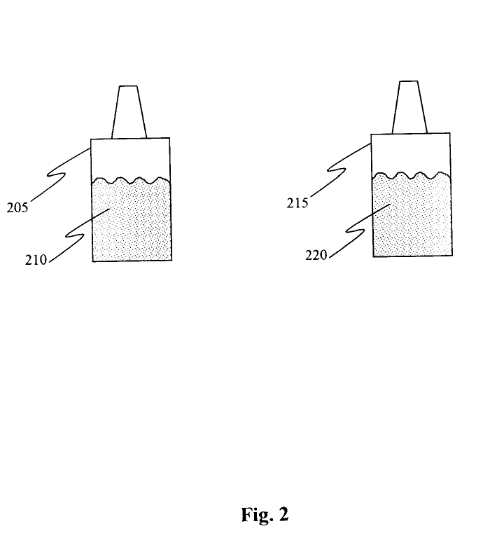

Illustrated in FIG. 1 is a flowchart of a method 100 for fabricating a semiconductor device according to various aspects of the present disclosure. FIGS. 2 to 5 illustrate diagrammatic views of a system for fabricating a semiconductor device according to the method 100 of FIG. 1. It is understood that FIGS. 2 to 5 have been simplified for a better understanding of the inventive concepts of the present disclosure. The semiconductor device may be an integrated circuit, or portion thereof, that may comprise static random access memory (SRAM) and/or other logic circuits, passive components such as resistors, capacitors, and inductors, and active components such as P-channel field effect transistors (pFET), N-channel FET (nFET), metal-oxide semiconductor field effect transistors (MOSFET), or complementary metal-oxide semiconductor (CMOS) transistors. It is understood that additional processes may be provided before, during, and after the method 100 of FIG. 1, and that some other processes may only be briefly described herein.

Referring to FIG. 1, the method 100 begins with block 110 in which a plurality of chemicals are stored in a plurality of storage units, wherein each storage unit is operable to store one of the plurality of chemicals. Referring to FIG. 2, a plurality of chemicals 210 and 220 are stored in a plurality of storage units 205 and 215, respectively. The chemicals 210 and 220 may be chemicals used in a semiconductor fabrication process. In the present embodiments, the chemicals 210 and 220 may be chemicals used in a photolithography process. The chemicals 210 and 220 may include the same type of chemicals or distinctively different types of chemicals. In addition, the storage units 205 and 215 may be the same type or different types, as long as each storage unit 205 and 215 is operable to store each of the chemicals 210 and 220, respectively. The storage units 205 and 215 may have relatively large volumes and may be operable to store chemicals 210 and 220 for a relatively long period before being used in the semiconductor fabrication process.

Several examples of the chemicals 210 and 220 are described below. In one example, chemicals 210 and 220 may be different photoresist materials from different vendors. The chemical 210 may have a better lithography performance compared to the chemical 220. For instance, chemical 210 may produce features having a smaller pitch or a better line-width roughness. However, the chemical 220 may produce fewer photoresist defects compared to chemical 210. The defects may include, but are not limited to, printing scum, silk scum, waterstain, critical dimension slimming, waterspot, photoresist softening, bubble, watermark, pattern fail, or fall-on defects. The chemical 220 may have a better defect control capability than the chemical 210 partly due to an additive in the chemical 220. The chemical 210 and chemical 220 may have a 1 to 1 volume or mass ratio. Alternatively, the ratio of chemical 210 to chemical 220 may be tuned by an user for a particular recipe to be performed. For example, the ratio of chemical 210 to chemical 220 is about 9 to 1, and the additive concentration in chemical 220 is about 10%. It is understood that other ratio values may be used depending on design requirements and the various vendors supplying the chemicals.

In another example, the chemicals 210 and 220 may be used for developing a photoresist. The chemical 220 may be a developer solution. For example, the developer solution may include a high concentration developer such as Tetra-methyl-ammonium hydroxide (TMAH). The developer solution may alternatively include de-ionized water (DIW). The chemical 210 may be a functional chemical for improving the photoresist development process. For instance, the chemical 210 may be a surfactant for relieving photoresist surface tension, removing photoresist surface defects, or improving photoresist line width roughness. The surfactant may be an ionic surfactant, such as NaC₄F₉SO₃ or NaC₈F₁₇SO₃. The surfactant may also be a non-ionic surfactant, such as C₄H₉OH, HOC₂H₄OH, or ethylene diamine. In another instance, the chemical 210 may include an acid such as HF or HCl for opening an under-layer of the photoresist. The under-layer may include a bottom anti-reflective coating (BARC) layer or a hard mask layer that is patterned with the photoresist. The chemical 210 may alternatively include a combination of the chemicals mentioned above.

In still another example, the chemicals 210 and 220 may be used for a freezing material or a silicon-containing middle layer used in a photolithography process. For instance, the chemical 210 may include a material used for freezing a photoresist at a fixed position during photoresist patterning, or the chemical 210 may include a material used for forming the silicon-containing middle layer to make a tighter pitch, and chemical 220 may include a chemical that may be mixed with chemical 210 before chemical 210 can be used. For example, chemicals 210 and 220 may each have a shelf-life of about 6 months when stored separately. However, when chemicals 210 and 220 are mixed together, the resulting mixture may have a shorter shelf-life of about 1 month. Therefore, in the third example, chemicals 210 and 220 are stored separately and then mixed together when they desired to be used in a semiconductor process. It is understood that the specified values are mere examples, and that various chemicals typically used in semiconductor manufacturing may have varying shelf-life periods.

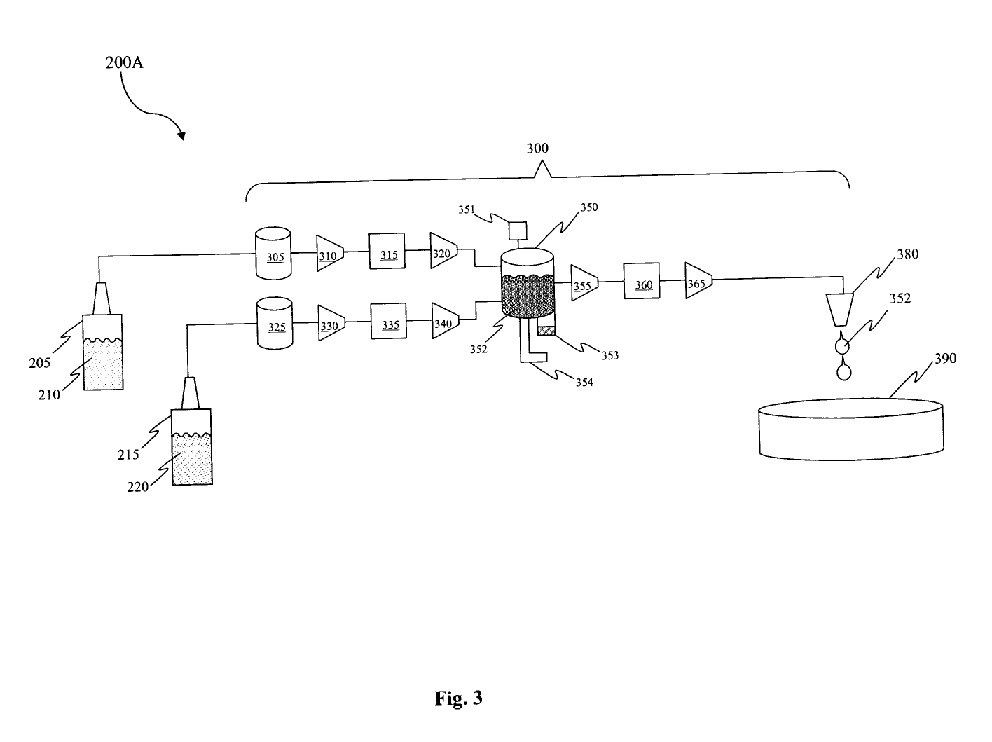

The method 100 continues with block 120 in which the chemicals are mixed into a mixture. Several embodiments of block 120 of the method 100 are described below in FIGS. 3-5. Referring now to FIG. 3, a first embodiment of a track nozzle system 200A is illustrated. The track nozzle system 200A includes the storage units 205 and 215 (in FIG. 2) and a track pipeline 300 having a plurality of components, including a plurality of tanks 305, 325, filters 310, 320, 330, 340, 355, 365, pumps 315, 335, 360, a mixer 350, and a nozzle 380. Portions of chemicals 210 and 220 may be dispensed into tanks 305 and 325, respectively. The amount may be tuned for a particular recipe, may be tuned for a production run, or may be adjusted in response to drifting of processing equipment. The tanks 305 and 325 may have smaller volumes in comparison to the storage units 205 and 215 and may be operable to temporarily store chemicals 210 and 220, respectively, before chemicals 210 and 220 have to be used. The tanks 305 and 325 may also act as buffers to relieve pressure in the track pipeline 300.

Next, the chemicals 210 and 220 may be filtered by filters 310 and 330, respectively. The filters 310 and 330 are operable to filter undesired particles from the chemicals 210 and 220, respectively. For example, the undesired particles may include impurities in the chemicals 210 and 220. After filtering, the chemicals 210 and 220 may be sent to pumps 315 and 335, respectively. The pumps 315 and 335 may be pressurized and operable to propagate the chemicals 210 and 220 into filters 320 and 340, respectively. The filters 320 and 340 may be similar to the filters 310 and 330, respectively, and filters 320 and 340 are operable to further filter undesired particles from chemicals 210 and 220, respectively. After being filtered by filters 320 and 340, the chemicals 210 and 220 may be sent to a mixer 350. The mixer 350 may be operable to mix the chemicals 210 and 220 into a mixture 352. In addition, the mixer 350 may be operable to temporarily store the mixture 352. The mixer 350 may also include a dispersion device 351 operable to propagate the mixture 352 through the track pipeline 300. The dispersion device 351 may be pressurized or electrically based. The mixer 350 may further include a temperature controller 353 to monitor and control a temperature inside the mixer 350 or the temperature of the mixture 352. The mixer 350 may also include a drain 354 operable to drain the mixture 352 out of the mixer 350. Next, the mixture 352 may be filtered again by a filter 355 to remove undesired particles from the mixture 352. After filtering, the mixture may be sent to a tank 360 operable to temporarily store the mixture 352 and act as a buffer to relieve pressure in the track pipeline 300. The mixture 352 may then be filtered by a filter 365 to further remove undesired particles.

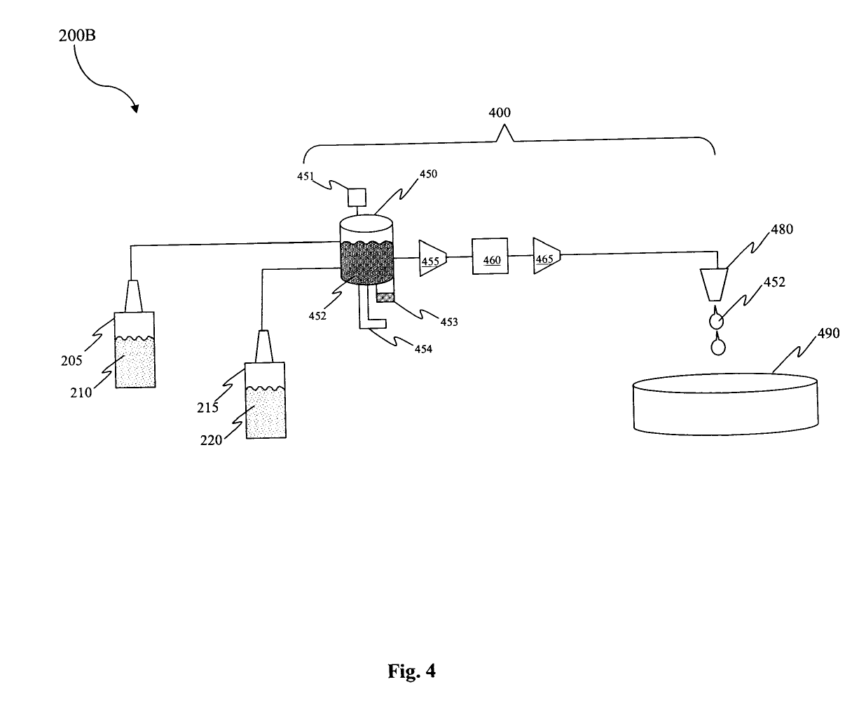

Referring now to FIG. 4, a second embodiment of a track nozzle system 200B is illustrated. The track nozzle system 200B includes the storage units 205 and 215 (in FIG. 2) and a track pipeline 400 having a plurality of components, including a mixer 450, a plurality of filters 455 and 465, a pump 460, and a nozzle 480. Portions of chemicals 210 and 220 may be dispensed into the mixer 450. The amount may be tuned for a particular recipe, may be tuned for a production run, or may be adjusted in response to drifting of processing equipment. The mixer 450 may be similar to the mixer 350 (in FIG. 3) described above and may also include a dispersion device 451, a temperature controller 453, and a drain 454. The mixture 452 may then be propagated out of the mixer 450 and sent to a filter 455, wherein the filter 455 may be operable to filter undesired particles from the mixture 452. For example, the undesired particles may include impurities in the mixture 452. After filtering, the mixture 452 may be sent to a pump 460. The pump 460 may be pressurized and operable to propagate the mixture 452 to the filter 465. The mixture 452 may then be filtered again by the filter 465 to further remove undesired particles.

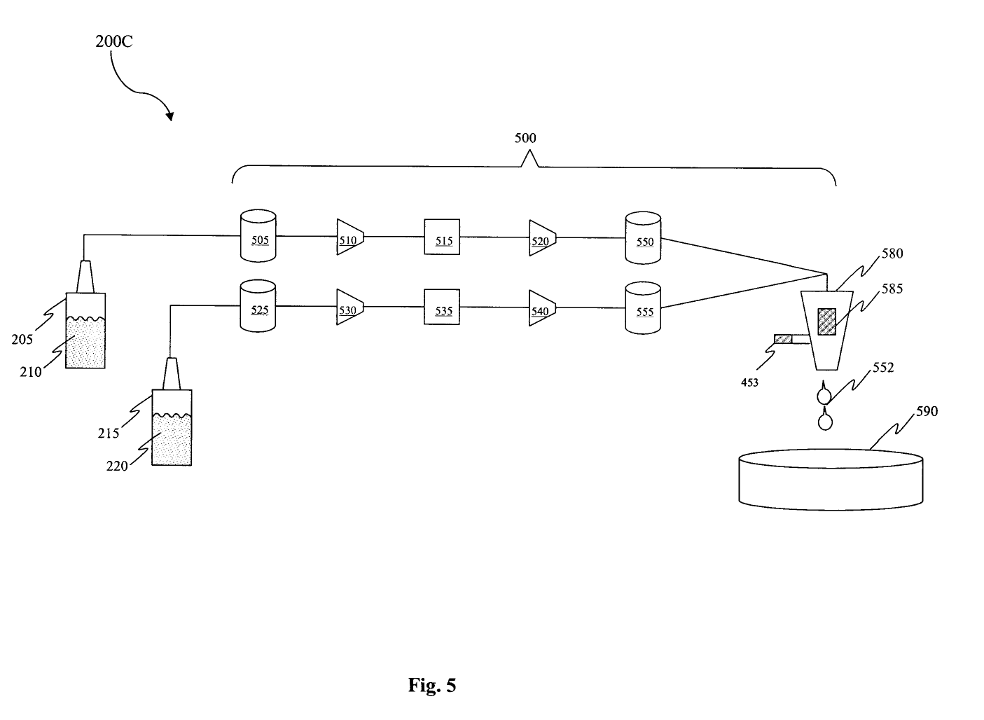

Referring now to FIG. 5, a third embodiment of a track nozzle system 200C is illustrated. The track nozzle system 200C includes the storage units 205 and 215 (in FIG. 2) and a track pipeline 500 having a plurality of components, including a plurality of tanks 505, 525, 550, 555, filters 510, 520, 530, 540, pumps 515, 535, and a mixing nozzle 580. Portions of chemicals 210 and 220 may be dispensed into tanks 505 and 525, respectively. The amount may be tuned for a particular recipe, may be tuned for a production run, or may be adjusted in response to drifting of processing equipment. The tanks 505 and 525 may be similar to the tanks 305 and 325 (in FIG. 3) described above and may also be operable to temporarily store the chemicals 210 and 220, respectively. The chemicals 210 and 220 may then be filtered by filters 510 and 530, respectively. The filters 510 and 530 are operable to filter undesired particles from the chemicals 210 and 220, respectively. For example, the undesired particles may include impurities in the chemicals 210 and 220. After filtering, the chemicals 210 and 220 may be sent to pumps 515 and 535, respectively. The pumps 515 and 535 may be pressurized and operable to propagate the chemicals 210 and 220 to the filters 520 and 540, respectively. The filters 520 and 540 are operable to further remove undesired particles from the chemicals 210 and 220. After leaving the filters 520 and 540, the chemicals 210 and 220 may then be temporarily stored by tanks 550 and 555, respectively. Next, the chemicals 210 and 220 may be sent to a mixing nozzle 580. The mixing nozzle 580 may include an integral mixer 585, wherein the mixer 585 is operable to mix chemicals 210 and 220 into a mixture 552.

The method 100 continues with block 130 in which the mixture is dispensed onto a wafer using a nozzle. The first embodiment of block 130 is illustrated in FIG. 3, wherein the nozzle 380 is coupled to the filter 365. The nozzle 380 may include a storage mechanism operable to receive the mixture 352 leaving the filter 365 and store the mixture 352 temporarily. The nozzle 380 may also include a dispensing mechanism operable to dispense the mixture 352 out of the nozzle 380. In the first embodiment, the mixture 352 leaves the filter 365 300 and is received by the nozzle 380. The mixture 352 may then be dispensed by the nozzle 380 onto a wafer 390.

The second embodiment of block 130 is illustrated in FIG. 4, wherein the nozzle 480 is coupled to the filter 465. The nozzle 480 may be similar to the nozzle 380 of first embodiment described above. In the second embodiment, the mixture 452 leaves the filter 465 and is received by the nozzle 480. The mixture 452 may then be dispensed by the nozzle 480 onto a wafer 490.

The third embodiment of block 130 is illustrated in FIG. 5, wherein the mixing nozzle 580 is coupled to the tanks 550 and 555. In addition to the mixer 585, the mixing nozzle 580 may also include a temperature controller 453 operable to control the temperature inside the mixer 580 or a temperature of the mixture 552. Further, the mixing nozzle 580 may include a storage mechanism to temporarily store the mixture 552. The mixing nozzle 580 may also include a dispensing mechanism operable to dispense the mixture 552 out of the mixing nozzle 580. In the third embodiment, the chemicals 210 and 220 form the mixture 552 inside the mixing nozzle 580 and may then be dispensed by the nozzle 580 onto a wafer 590.

It is understood that the sequencing of the components in the track pipelines 300, 400, and 500 may be changed without departing from the spirit of the invention. Further, the number of the tanks, filters, and pumps may be varied. For example, although FIG. 3 shows three pumps 315, 335, 360 for the first embodiment, the first embodiment may be realized with only two pumps 315, 335, or alternatively with an additional pump elsewhere along the track pipeline 300. Furthermore, the track pipelines 300, 400, and 500 may receive more than the two chemicals 210 and 220 shown in the present embodiments, and may be configured to mix any combination of the chemicals as desired.

It is also understood that the method 100 may continue with additional steps. For example, in the first embodiment, after the mixture 352 is dispensed onto the wafer as photoresist, the method 100 may continue with soft-baking, masking and exposing the photoresist, post exposure baking, developing the photoresist, patterning a hard mask with the photoresist, and removing the photoresist.

Further, it is understood that multiple track nozzle systems may be used depending on the needs of production. A plurality of chemicals may be stored in an easily accessible location, and each track nozzle system may be independently programmed to select the chemicals needed for its own production purposes and/or to produce different recipes.

In summary, the methods and devices disclosed provide an effective approach to fabricate a semiconductor device. The method disclosed herein takes advantage of storing multiple chemicals separately, mixing the chemicals into a mixture, and dispensing the mixture onto a wafer with a single nozzle. Accordingly, two or more chemicals can be applied at the same time using one nozzle. Thus, the embodiments disclosed herein are applicable in various semiconductor processes that implement a single dispensing nozzle such as a coater resist dispensing nozzle, a developer dispensing nozzle, a de-ionized dispensing nozzle, and a firm dispensing nozzle.

The embodiments disclosed herein offer several advantages over traditional methods. It is understood that different embodiments disclosed herein offer different advantages, and that no particular advantage is necessarily required for all embodiments. For example, when chemicals 210 and 220 are photoresist materials that have different photolithography performances and defect control capabilities, traditional methods would require an user to choose between either one photolithography performance and defect control capability. In comparison, the present embodiments combines chemicals 210 and 220 into the mixture 352 of any ratio that exhibits both good lithography performance and defect control capability. The embodiments disclosed herein also offer advantages by allowing a mixing of a functional chemical with a developer solution. The mixing allows for a larger design window of a photolithography process. In addition, the mixing allows for a high concentration developer solution such as TMAH. Further, the mixing allows for effective defect control. The embodiments disclosed herein may also alleviate shelf-life concerns that may exist in semiconductor fabrication processes. With traditional methods, one nozzle is typically available for one chemical. Consequently, the chemicals 210 and 220 would have to be mixed together to create a mixture that is stored in a storage unit. Due to the complex nature of semiconductor fabrication, it may be difficult to predict exactly when the mixture would be used. Nevertheless, the mixture has to be prepared and be available for use. It is possible that the mixture would be stored in the storage unit for months without being used. However, the mixture may have a typical shelf-life of about 1 month for example. Consequently, the mixture may go bad before being used. In the present embodiments, the chemicals 210 and 220 are stored separately in storage units 205 and 215, respectively. The chemicals 210 and 220 have a typical shelf-life of about 6 months when stored separately. A mixture of chemicals 210 and 220 is formed only when production needs call for it. Hence, the relatively short shelf-life of the mixture does not become an issue in the embodiments disclosed herein.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, the methods and systems disclosed herein are applicable to various semiconductor processes that involve dispensing chemicals and/or mixtures in fabricating semiconductor devices.

What is claimed is:

1. A method of fabricating a semiconductor device using a track pipline system, comprising:
storing a plurality of chemicals in a plurality of storage units of the system, wherein each storage unit is operable to store one of the chemicals;
mixing the chemicals into a mixture; and
dispensing the mixture onto a wafer using a nozzle of the system.

2. The method of claim 1, further comprising:
storing at least a portion of the mixture;
filtering undesired particles from the mixture; and
propagating the mixture.

3. The method of claim 2, further comprising controlling a temperature of the mixture.

4. The method of claim 3, further comprising after dispensing the mixture, performing a photolithography process to the wafer.

5. A system, comprising:
a first storage unit operable to store a first chemical and a second storage unit operable to store a second chemical; and
a track pipeline coupled to the first and second storage units and operable to receive the first and second chemicals from the first and second storage units, the track pipeline including:
a filter operable to filter undesired particles from one of the first and second chemicals;
a pump operable to propagate one of the first and second chemicals through the track pipeline;
a mixer operable to mix the first and second chemicals into a mixture; and
a nozzle operable to receive the mixture and dispense the mixture onto a wafer.

6. The system of claim 5, wherein the track pipeline further includes a tank operable to temporarily store one of the first and second chemicals.

7. The system of claim 6, wherein the mixer includes a temperature controller operable to monitor and control a temperature inside the mixer.

8. The system of claim 7, wherein the mixer includes a drain operable to drain the mixture out of the mixer.

9. The system of claim 8, wherein the mixer includes a dispersion device operable to propagate the mixture through the system, and wherein the dispersion device is pressurized or electrically based.

10. The system of claim 5, wherein the mixer is integrated into the nozzle.

11. The system of claim 5, wherein the first chemical includes a first photoresist, and the second chemical includes a second photoresist, wherein the first photoresist has a better photolithography performance than the second photoresist, and the second photoresist has a better defect control capability than the first photoresist.

12. The system of claim 5, wherein the first chemical an acid or a surfactant, and wherein the second chemical includes TMAH or DIW.

13. The system of claim 12, wherein the acid includes HF or HCl, and the surfactant includes NaC₄F₉SO₃, NaC₈F₁₇SO₃, C₄H₉OH, HOC₂H₄OH, or ethylene diamine.

14. The system of claim 5, wherein the first chemical and second chemical each has a longer shelf-life than a shelf-life of the mixture.

15. A track pipeline system, comprising:
a plurality of storage units each operable to store one of a plurality of chemicals;
a mixer coupled to each of the storage units, the mixer being operable to receive the chemicals and mix the chemicals into a mixture;
a filter coupled to the mixer, the filter being operable to filter undesired particles from the mixture;
a pump operable to propagate the mixture through the system; and
a nozzle operable to receive the mixture and dispense the mixture onto a wafer.

16. The system of claim 15, wherein the mixer is integrated into the nozzle.

17. The system of claim 15, wherein the mixer includes a temperature controller operable to monitor and control a temperature inside the mixer.

18. The system of claim 15, wherein the chemicals include a first photoresist and a second photoresist, wherein the first photoresist has a better photolithography performance than the second photoresist, and the second photoresist has a better defect control capability than the first photoresist.

19. The system of claim 15, wherein the chemicals include a developer solution and a functional chemical, wherein the developer solution includes TMAH or DIW, and wherein the functional chemical includes HF, HCl, NaC₄F₉SO₃, NaC₈F₁₇SO₃, C₄H₉OH, HOC₂H₄OH, or ethylene diamine.

20. The system of claim 15, wherein the chemicals each has a longer shelf-life than a shelf-life of the mixture.
